(19) United States
(12) Patent Application Publication
(10) Pub. No.: US 2013/0160825 A1
(43) Pub. Date: Jun. 27, 2013

(54) BACK CONTACT PHOTOVOLTAIC MODULE WITH GLASS BACK-SHEET

(71) Applicant: E I DU PONT DE NEMOURS AND COMPANY, Wilmington, DE (US)

(72) Inventors: THOMAS D. LANTZER, Wake Forest, NC (US); DILIP NATARAJAN, Wilmington, DE (US)

(73) Assignee: E I DU PONT DE NEMOURS AND COMPANY, Wilmington, DE (US)

(21) Appl. No.: 13/723,596

(22) Filed: Dec. 21, 2012

Related U.S. Application Data
(60) Provisional application No. 61/579,014, filed on Dec. 22, 2011.

(51) Int. Cl. H01L 31/05; H01L 31/18

(52) U.S. Cl. CPC H01L 31/0516; H01L 31/18
USPC 136/251; 438/64

(57) ABSTRACT

An integrated back sheet for a back-contact solar cell module and a back-contact solar cell module made with an integrated glass back-sheet are provided. Processes for making such integrated back-sheets and back-contact solar cell modules are also provided. Elongated electrically conductive wires are mounted on a layer of the integrated back-sheet adhered to the glass back-sheet. The elongated electrically conductive wires of the integrated back-sheet electrically connect to solar cell back contacts when the back-sheet is used in a back-contact photovoltaic module.

### FIELD OF THE INVENTION

The present invention relates to back-contact photovoltaic modules with glass back-sheets, and to processes for making such photovoltaic modules with conductive circuitry integrated into the modules.

### BACKGROUND

A photovoltaic cell converts radiant energy, such as sunlight, into electrical energy. In practice, multiple photovoltaic cells are electrically connected together in series or in parallel and are protected within a photovoltaic module or solar module.

As shown in FIG. 1, a photovoltaic module 10 typically comprises a light-transmitting front sheet substrate 12, a front encapsulant layer 14, an active photovoltaic cell layer 16, a rear encapsulant layer 18 and a back-sheet 20. The light-transmitting front sheet substrate may be comprised of glass or plastic, such as, polycarbonate, acrylic, polyacrylate, cyclic polyolefin, polystyrene, polyamide, polyester, silicon polymers and copolymers, fluoropolymers and the like, and combinations thereof. The front and back encapsulant layers 14 and 18 adhere the photovoltaic cell layer 16 to the front and back sheets, they seal and protect the photovoltaic cells from moisture and air, and they protect the photovoltaic cells against physical damage. The encapsulant layers 14 and 18 are typically comprised of a thermoplastic or thermosetting resin such as ethylene-vinyl acetate copolymer (EVA). The photovoltaic cell layer 16 is made up of any type of photovoltaic cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The module layers need to remain intact and adhered for the service life of the photovoltaic module, which may extend for multiple decades. The photovoltaic cells typically have electrical contacts on both the front and back sides of the photovoltaic cells. However, contacts on the front sunlight receiving side of the photovoltaic cells can cause up to a 10% shading loss.

In back-contact photovoltaic cells, all of the electrical contacts are moved to the back side of the photovoltaic cell. With both the positive and negative polarity electrical contacts on the back side of the photovoltaic cells, electrical circuitry is needed to provide electrical connections to the positive and negative polarity electrical contacts on the back of the photovoltaic cells. U.S. Patent Application No. 2011/0067751 discloses a back contact photovoltaic module with a back-sheet having patterned electrical circuitry that connects to the back contacts on the photovoltaic cells during lamination of the solar module. The circuitry is formed from a metal foil that is adhesively bonded to a carrier material such as polyester film or Kapton® film. The carrier material may be adhesively bonded to a protective layer such as a Tedlar® fluoropolymer film. The foil is patterned using etching resists that are patterned on the foil by photolithography or by screen printing according to techniques used in the flexible circuitry industry. The back contacts on the photovoltaic cells are adhered to and electrically connected to the foil circuits by adhesive conductive paste. There is a need for alternative back-contact photovoltaic modules in which conductive circuitry is integrated with a rigid glass back-sheet. There is also a need for moisture impermeable back-sheets that maintain moisture integrity for the long service life of the photovoltaic modules which may extend for decades. There is also a need for photovoltaic back contact modules in which the back contacts securely attach to the conductive circuitry and remain securely attached for multiple decades.

### BRIEF DESCRIPTION OF THE DRAWINGS

The detailed description will refer to the following drawings which are not drawn to scale and wherein like numerals refer to like elements:

FIG. 1 is cross-sectional view of a conventional solar cell module.

FIGS. 2a and 2b are schematic plan views of the back side of arrays of back-contact solar cells.

FIGS. 3a and 3b are schematic representations of back-sheets with integrated wire circuits.

FIG. 4a is a plan view of a wire mounting layer with adhered conductive wires, and FIG. 4b is a plan view of the wire mounting layer after the conductive wires have been selectively cut.

FIG. 5a is a plan view of a an interlayer dielectric (ILD), and FIG. 5b is a plan view of the ILD in which holes or openings have been formed or cut out.

FIGS. 6a-6e are cross-sectional views illustrating one disclosed process for forming a back-contact solar cell module in which integrated conductive wires are connected to the back contacts of solar cells.

FIG. 7 is a cross-sectional view illustrating one disclosed process for forming a back-contact solar cell module in which integrated conductive wires are connected to the back contacts of solar cells.

FIGS. 8a and 8b are cross-sectional views illustrating one disclosed process for forming a back-contact solar cell module in which integrated conductive wires are connected to the back contacts of solar cells.

FIG. 9a is a plan view of a polymeric wire mounting layer, and FIG. 9b is a plan view of the wire mounting layer in which holes or openings have been formed or cut out. FIGS. 9c illustrates the application of conductive wires to the wire mounting layer, and FIG. 9d illustrates the application of a polymeric layer over the conductive wires.

FIGS. 10a-10f illustrate steps of a process for forming a back-contact solar cell module in which an array of back-contact solar cells are electrically connected in series by conductive wires that are integrated with a glass back-sheet of the solar cell module.

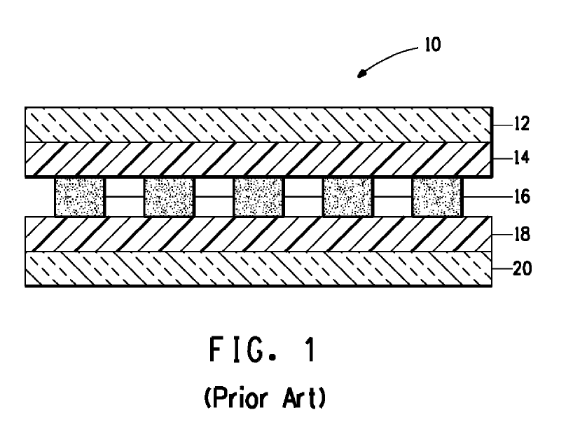

### DETAILED DESCRIPTION OF THE INVENTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

As used herein, the terms “sheet”, “layer” and “film” are used in their broad sense interchangeably. A “front sheet” is a sheet, layer or film on the side of a photovoltaic module that faces a light source and may also be described as an incident layer. Because of its location, it is generally desirable that the front sheet has high transparency to the incident light. A “back-sheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

As used herein, “encapsulant” layers are used to encase the fragile voltage-generating photoactive layer, to protect it from environmental or physical damage, and hold it in place in the photovoltaic module. Encapsulant layers may be positioned between the solar cell layer and the front incident layer, between the solar cell layer and the back-sheet, or both. Suitable polymer materials for the encapsulant layers typically possess a combination of characteristics such as high transparency, high impact resistance, high penetration resistance, high moisture resistance, good ultraviolet (UV) light resistance, good long term thermal stability, good long term weatherability, and adequate adhesion strength to frontsheets, back-sheets, other rigid polymeric sheets and solar cell surfaces.

As used herein, “inter layer dielectric” (ILD) is a layer of a low dielectric constant k material used to electrically separate closely spaced electrically conductive layers or lines arranged in several levels of an electrical circuit or device such as a photovoltaic module.

As used herein, the terms “photoactive” and “photovoltaic” may be used interchangeably and refer to the property of converting radiant energy (e.g., light) into electric energy.

As used herein, the terms “photovoltaic cell” or “photoactive cell” or “solar cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” or “solar cell” are used herein to include photovoltaic cells with any types of photoactive layers including, crystalline silicon, polycrystalline silicon, microcrystal silicon, and amorphous silicon-based solar cells, copper indium (gallium) diselenide solar cells, cadmium telluride solar cells, compound semiconductor solar cells, dye sensitized solar cells, and the like.

As used herein, the term “photovoltaic module” or “solar module” (also “module” for short) means an electronic device having at least one photovoltaic cell protected on one side by a light transmitting front sheet and protected on the opposite side by an electrically insulating protective back-sheet.

As used herein, the term “back-contact solar cell” means a solar cell having both positive and negative polarity contacts located on its back side, including metal wrap through (MWT), metal wrap around (MWA), emitter wrap through (EWT), emitter wrap around (EWA), and interdigitated back contact (IBC) solar cells.

Disclosed herein are back-contact solar modules with a glass back-sheet and integrated conductive wire circuitry and processes for forming such back-contact solar modules with integrated circuitry.

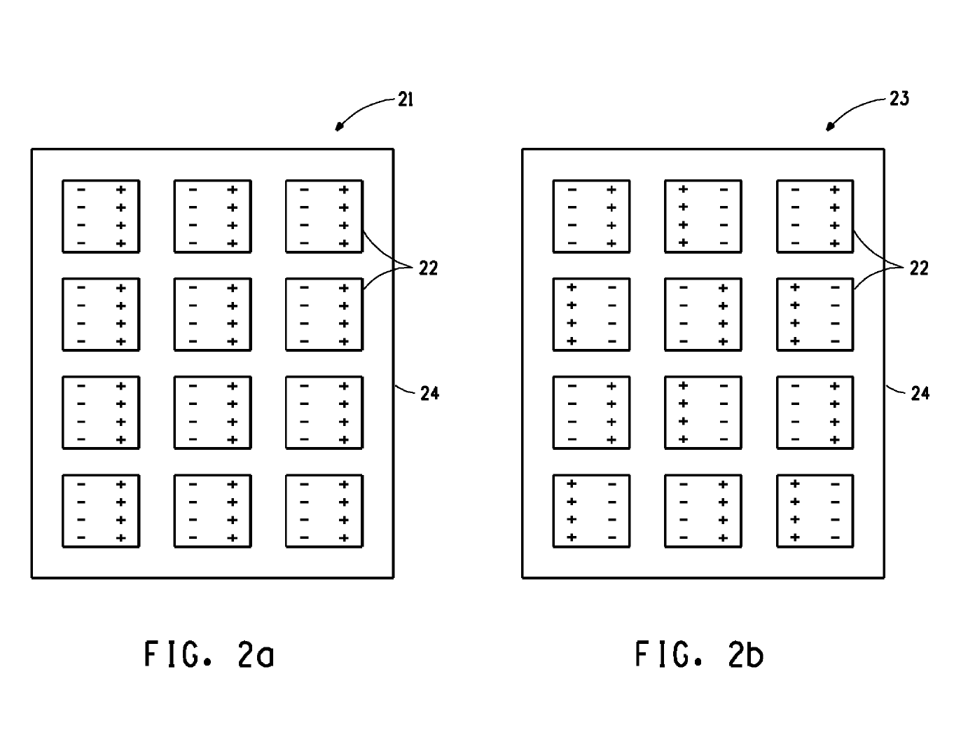

Arrays of back-contact solar cells are shown in FIGS. 2a and 2b. The disclosed glass back-sheet and conductive circuitry is useful for protecting and electrically connecting back-contact solar cell arrays like those shown in FIGS. 2a and 2b. The solar cell array 21 shown in FIG. 2a includes multiple solar cells 22, such as single crystal silicon solar cells. The front side (not shown) of each solar cell 22 is adhered to an encapsulant layer 24 that is or will be preferably adhered to a transparent front sheet (not shown) of the solar module. Solar modules with an array of twelve solar cells 22 are shown in FIGS. 2a and 2b, but the disclosed integrated back-sheet is useful as a back-sheet for back-contact solar modules having solar cell arrays of anywhere from four to more than 100 solar cells.

Each of the solar cells 22 has multiple positive and negative polarity contacts on back side of the solar cell. The contacts on the back side of the solar cells are typically made of a metal to which electric contacts can be readily formed, such as silver or platinum contact pads. The contacts are typically formed from a conductive paste comprising an organic medium, glass frit and silver particles, and optionally inorganic additives, which is fired at high temperature to form metal contact pads. The solar cells shown in FIGS. 2a and 2b each have a column of four negative polarity contacts and a column of four positive polarity contacts, but it is contemplated that the solar cells could have multiple columns of negative and positive polarity contacts and that each column could have anywhere form two to more than twenty contacts. In the solar cell array shown in FIG. 2a, the contacts of each cell are arranged in the same way. The arrangement shown in FIG. 2a is used with the disclosed glass back-sheet and conductive circuitry when the cells are connected in parallel. Alternatively, the solar cells in each column of the array can be arranged such that the alternating cells in each column are rotated 180 degrees as shown in FIG. 2b. The solar cell array 23 shown in FIG. 2b is used with the disclosed glass back-sheet and conductive circuitry is used to connect the solar cells in series, as will be described more fully below.

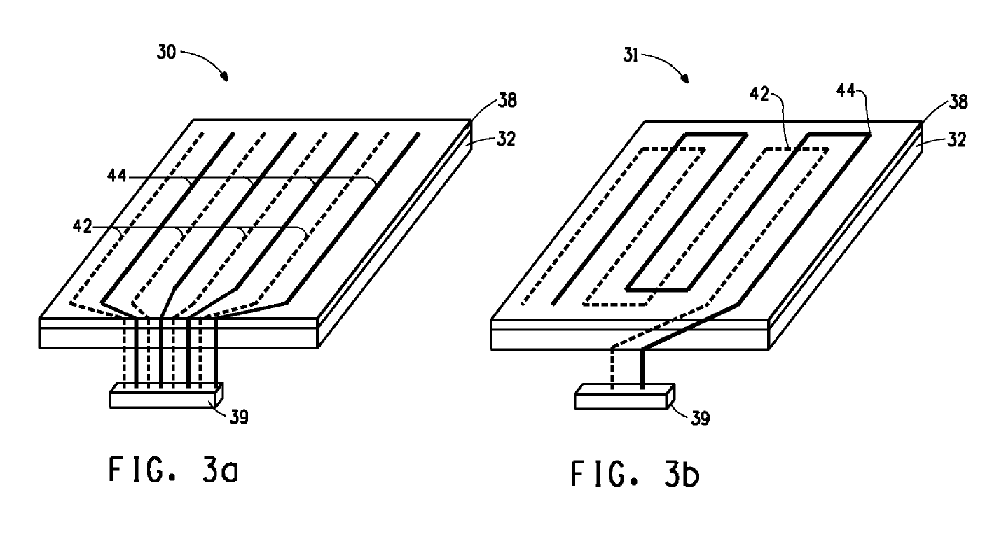

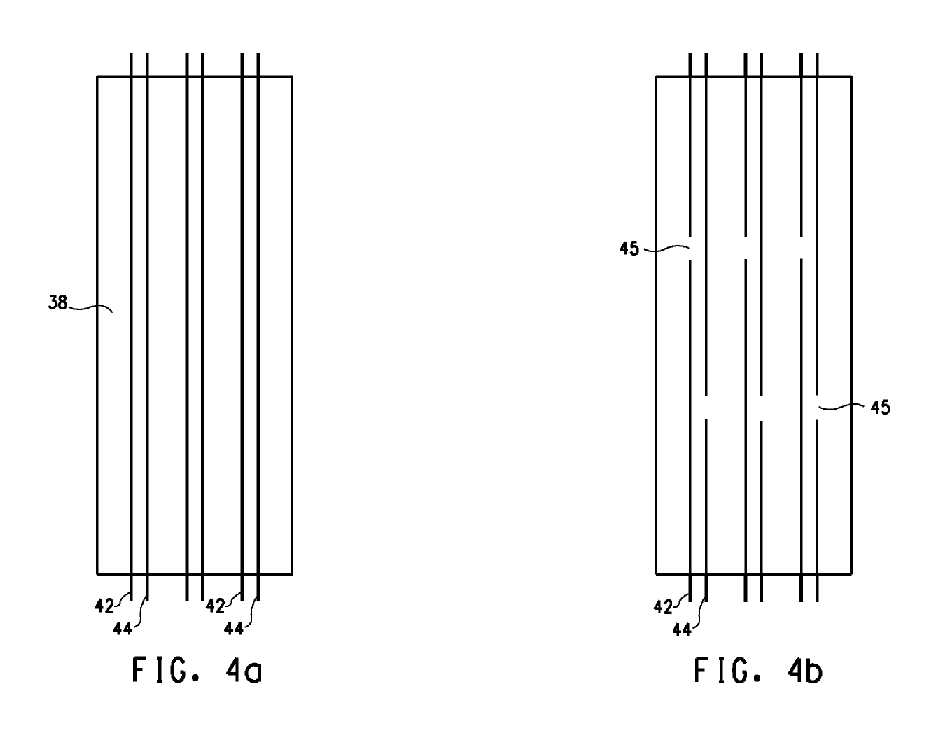

FIG. 3a shows an embodiment of the disclosed integrated back-sheet. The integrated back-sheet 30 shown in FIG. 3a comprises a glass back-sheet 32, a polymeric wire mounting layer 38, and conductive wires 42 and 44. The glass sheet 32 has a surface that faces the wire mounting layer 38 and an opposite side that forms an exposed surface on the back of a photovoltaic module into which the back-sheet is incorporated. The glass sheet 32 is preferably made of a strong shatter proof glass. The thickness of the glass depends in part on area of the module and the inherent strength of the glass material. For back-contact photovoltaic modules with typical areas of from 1 to 2 m², a back-sheet glass thickness of from 1.5 mm to 4 mm is preferred. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass and the like. Low lead glass is preferred for environmental reasons. When glass is used for the back-sheet, it may be possible to replace a glass front sheet with a flexible front sheet such as a polymeric front sheet in a rigid photovoltaic module. Because the back-sheet is not required to be highly transparent in most instances, as is the case with a front sheet glass, the use of a glass back-sheet rather than a glass front sheet makes it possible to use a less specialized and less costly glass sheet in the module. The type of glass to be selected for a particular laminate depends on the intended use.

In the embodiment of the disclosed integrated glass back-sheet 30 shown in FIG. 3a, multiple wires are adhered or partially embedded in the wire mounting layer 38 in a generally parallel arrangement. Where the back-sheet is used to connect like mounted solar cells like those shown in FIG. 2a, each set of wires 42 and 44 connect to negative and positive contacts, respectively, of a column of solar cell contacts so as to electrically connect the column of cells in parallel. Were the integrated back-sheet is used to connect solar cells in series, every other cell in a column of cells can be rotated 180 degrees as shown in FIG. 2b and the wires 42 and 44 can be selectively cut to connect adjacent cells in series in a column of solar cells as more fully described below.

In the integrated back-sheet 31 shown in FIG. 3b, a wire mounting layer is provided on the glass back-sheet 32. The wire mounting layer 38 holds the wires 42 and 44 in place and attaches them to the glass sheet 32. The wires 42 and 44 are adhered to the surface or partially embedded in the wire mounting layer with a surface of the wires 42 and 44 being exposed. The wire 42 is more deeply embedded in the wire mounting layer at places where the wires 42 and 44 cross paths or an insulating pad is inserted between the wires at the cross over points. When the solar cells are connected in parallel, the wire 42 is connected to the solar cell back contacts of one polarity and the wire 44 is connected to the solar cell back contacts of the opposite polarity. The wires 42 and 44 may be embedded under the surface of the wire mounting layer 38 in which case the wire mounting layer 38 will have holes formed in it at points where the wires 42 and 44 make electrical contact with solar cell back contacts. Such holes may be formed, for example, by stamping or die cutting.

The wire mounting layer 38 preferably comprises a polymeric material such as a thermoplastic or thermoset material. The wire mounting layer 38 preferably has a thickness sufficient to be self supporting and sufficient to support wires mounted on the wire mounting layer. For example, the wire mounting layer typically has a thickness in the range of 1 mils to 25 mils, and more preferably in the range of 4 mils to 18 mils. The wire mounting layer can include more than one layer of polymer material, wherein each layer may include the same material or a material different from the other layer(s). The wire mounting layer may be comprised of polymer with adhesive properties, or an adhesive coating can be applied to the surface(s) of the wire mounting layer to hold the wires in place. The side of the wire mounting layer opposite to the electrically conductive wires attaches to the glass back-sheet. The wire mounting layer may be formed of a polymeric material that adheres directly to the glass back-sheet during thermal lamination of the photovoltaic module. Alternatively, adhesives such as reactive adhesives (e.g., polyurethane, acrylic, epoxy, polyimide, or silicone adhesives) or non-reactive adhesives (e.g., polyethylenes (including ethylene copolymers) or polyesters) can be used to attach the wire mounting layer to the glass back-sheet.

Depending upon when the conductive wires are anchored to the back contacts of the solar cells, it may be desirable for the wire mounting layer to be made of a polymer that does not melt or deform when the photovoltaic module is laminated. As more fully discussed below, when the conductive wires have already been anchored to the solar cell back contacts prior to lamination of the photovoltaic module, it may be less of an issue if the wire mounting layer deforms or melts during lamination of the photovoltaic module. If, on the other hand, the conductive wires are anchored to the back contacts of the solar cells during the lamination of the photovoltaic module or if the wire mounting layer must act to electronically insulate the wires from the back side of the solar cells, it will be important that the wire mounting layer not melt or deform during the module lamination step. Where the wire mounting layer must not melt or deform, the wire mounting layer should be formed of a polymer with a melting temperature that is higher than the module lamination temperature. Cross-linked or cured encapsulant materials typically have softening and melting temperatures above the module lamination temperature, which typically range from 120° C. to 180° C. Polymeric materials useful in the wire mounting layer include ethylene methacrylic acid and ethylene acrylic acid, ionomers derived therefrom, or combinations thereof. Exemplary comonomers that may be in the precursor acid copolymers include, but are not limited to, methyl acrylates, methyl methacrylates, butyl acrylates, butyl methacrylates, glycidyl methacrylates, vinyl acetates, and mixtures of two or more thereof.

The wire mounting layer may also be films or sheets comprising poly(vinyl butyral)(PVB), ionomers, ethylene vinyl acetate (EVA), poly(vinyl acetals) (including acoustic grade poly(vinyl acetals)), polyurethanes, polyvinylchlorides, polyethylenes, polyolefin block elastomers, copolymers of a-olefins and a,β-ethylenically unsaturated carboxylic acid esters (e.g., ethylene methyl acrylate copolymers and ethylene butyl acrylate copolymers), silicone elastomers, polycarbonate resins, epoxy resins, nylon resins and combinations of two or more thereof. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn lonomer Resins”, Polyelectrolytes, 1976, C, 177-197. Other suitable ionomers are further described in European patent EP1781735, which is herein incorporated by reference.

Ethylene copolymers which may be used as an adhesive in the wire mounting layer are more fully disclosed in PCT Patent Publication No. WO2011/044417 which is hereby incorporated by reference. Such ethylene copolymers are comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer preferably accounts for 60-90% by weight. A preferred ethylene copolymer adhesive layer includes a copolymer of ethylene and another a-olefin. The ethylene content in the copolymer accounts for 60-90% by weight, preferably accounting for 65-88% by weight, and ideally accounting for 70-85% by weight of the ethylene copolymer. The other comonomer(s) preferably constitute 10-40% by weight, preferably accounting for 12-35% by weight, and ideally accounting for 15-30% by weight of the ethylene copolymer. The ethylene copolymer adhesive layer is preferably comprised of at least 70 weight percent of the ethylene copolymer. The ethylene copolymer may be blended with up to 30% by weight, based on the weight of the adhesive layer, of other thermoplastic polymers such as polyolefins, as for example linear low density polyethylene, in order to obtain desired properties. Ethylene copolymers are commercially available, and may, for example, be obtained from DuPont under the trade-name Bynel®.

The wire mounting layer may further contain additives, fillers or reinforcing agents known within the art. Such exemplary additives include, but are not limited to, plasticizers, processing aides, flow enhancing additives, lubricants, pigments, titanium dioxide, calcium carbonate, dyes, flame retardants, impact modifiers, nucleating agents to increase crystallinity, antiblocking agents such as silica, thermal stabilizers, hindered amine light stabilizers (HALS), UV absorbers, UV stabilizers, anti-hydrolytic agents, dispersants, surfactants, chelating agents, coupling agents, adhesives, primers, reinforcement additives, such as glass fiber, and the like. There are no specific restrictions to the content of the additives and fillers in the wire mounting layer as long as the additives do not produce an adverse impact on the adhesion properties or stability of the layer.

A polymeric wire mounting layer 38 is shown in FIG. 4a. Substantially parallel pairs of electrically conductive wires 42 and 44 are shown on the wire mounting layer. Three pairs of wires 42 and 44 are shown in FIG. 4a, but it is contemplated that more or fewer pairs of wires could be used depending upon the number of columns of solar cells in the solar cell array, and depending on the number of columns of back contacts on each of the solar cells. It is also contemplated that the spacing of the wires and the wire pairs will depend upon the spacing of the columns of solar cells in the array, and on the arrangement and spacing of the columns of back contacts on each of the solar cells. The wire mounting layer is in the form of an elongated strip that covers at least one column of solar cells in the solar cell array, and preferably covers multiple columns of solar cells in the solar cell array, or may cover all of the columns of solar cells in the solar cell array.

The wires 42 and 44 are preferably conductive metal wires or metal foil strips. The metal wires are preferably comprised of metal selected from copper, nickel, tin, silver, aluminum, indium, lead, and combinations thereof. In one embodiment, the metal wires are coated with tin, nickel or a solder and/or flux material. Where the wires are coated with a solder and optionally with a flux, the wires can more easily be soldered to the back contacts of the solar cells as discussed in greater detail below. For example, aluminium wires may be coated with an aluminum/silver alloy that can be easily soldered using conventional methods. Where the wires are coated with solder, such as an alloy, the solder may be coated on the wires along their full length or only on the portions of the wires that will come into contact with the solar cell back contacts in order to reduce the amount of the coating material used. The conductive wires may be coated with an electrically insulating material such as a plastic sheath so as to help prevent short circuits in the solar cells when the wires are positioned over the back of an array of solar cells. Where the conductive wires are coated with an insulating material, the insulating material can be formed with breaks where the wires are exposed to facilitate the electrical connection of the wires to the back contacts of the solar cells. Alternatively, the insulating material may be selected such that it will melt or burn off when the wires are soldered or welded to the back contacts on the solar cells. The electrically conductive wires preferably each have a cross sectional area of at least 70 square mils along their length, and more preferably have a cross sectional area of at least 200 square mils along their length, and more preferably have a cross sectional area of 500 to 1200 square mils along their length. This wire cross section provides the strength, current carrying ability, low bulk resistivity, and wire handling properties desired for module efficiency and manufacturability. The electrically conductive wires may have any cross sectional shape, but ribbon shaped wires or tabbing wires having a width and thickness where the wire width is at least three times greater than the wire thickness, and more preferably where the wire width is 3 to 15 times the wire thickness, have been found to be especially well suited for use in the integrated back-sheet because wider wires makes it easier to align the wires with the back contacts of the solar cells when the wire mounting layer is applied to an array of back-contact solar cells.

The wire mounting layer 38 should be long enough to cover multiple solar cells, and is preferably long enough to cover all of the solar cells in a column of solar cells in the solar cell array, and may even be long enough to cover columns of solar cells in multiple solar cell arrays, as for example where the wires are applied to a long strip of the wire mounting layer in a continuous roll-to-roll process. For example, the wire mounting layer and the electrically conductive wires can be continuously fed into a heated nip where the wires are brought into contact with and adhered to the wire mounting layer by heating the wire mounting layer at the nip so as to make it tacky. Alternatively, the wire mounting layer can be die extruded with the wires fed into the wire mounting layer during the extrusion process. In another embodiment, the wires and the wire mounting layer can be heated and pressed in a batch lamination press to partially or fully embed the wires into the wire mounting layer. Pressure may be applied to the wires at the heated nip so as to partially or fully embed the conductive wires in the wire mounting layer. Preferably a surface of the wires remains exposed on the surface of the wire mounting layer after the wire is partially or fully embedded in the wire mounting material so that it will still be possible to electrically connect the wires to the back contacts of an array of back-contact solar cells.

Where the solar cells of the solar cell array will be connected in parallel, the full length wires can be used as shown in FIG. 4a and subsequently connected to a column of solar cells like one of the solar cell columns shown in FIG. 2a. Where the solar cells of the array will be connected in series, the wires are cut at selected points 45 as shown in FIG. 4b and connected to a column of solar cells where alternating cells have been rotated by 180 degrees, like one of the columns of solar cells shown in FIG. 2b, and as more fully described below. Cutting the wires can be performed by a variety of methods including mechanical die cutting of the wires. The underlying wire mounting layer may also be punched out at selected locations along with the wires.

In order to prevent electrical shorting of the solar cells, it may be necessary to apply an electrically insulating dielectric material between the conductive wires and the back of the solar cells of the back-contact solar cell array. This dielectric layer is provided to maintain a sufficient electrical separation between the conductive wires and the back of the solar cells. The dielectric layer, known as an interlayer dielectric (ILD), may be applied as a sheet over all of the wires and the wire mounting layer, or it may be applied as strips of dielectic material over only the electrically conductive wires. It is necessary to form openings in the ILD, as for example by die cutting or punching sections of the ILD, that will be aligned over the back contacts of the solar cells and through which the back contacts will be electrically connected to the conductive wires. Alternatively, the ILD may be applied by screen printing. The printing can be on the back side of the solar cells or on the wire mounting layer and wires, and can cover the entire area between the wire mounting layer and the solar cell array or just selected areas where the wires are present. A printed ILD layer can be UV cured after application so that the ILD will remain in place throughout module lamination and use. Where the ILD is printed, it may be printed only in the areas where the wires need to be prevented from contacting the back of the solar cells. The ILD can be applied to the wires and the wire mounting layer or it can be applied to the back of the solar cells before the conductive wires and the wire mounting layer are applied over the back of the solar cell array. Alternatively, the ILD may be applied as strips over the wires on the wire mounting layer or as strips over the portions of the back side of the solar cells over which the conductive wires will be positioned. The thickness of the ILD will depend in part on the insulating properties of the material comprising the ILD, but preferred polymeric ILDs have a thickness in the range of 5 to 500 microns, and more preferably 10 to 300 microns and most preferably 25 to 200 microns.

Where the conductive wires have a complete insulating coating or sheath, it may be possible to eliminate the ILD between the electrically conductive wires of the integrated back-sheet and the back side of the back-contact solar cells to which the integrated back-sheet is applied.

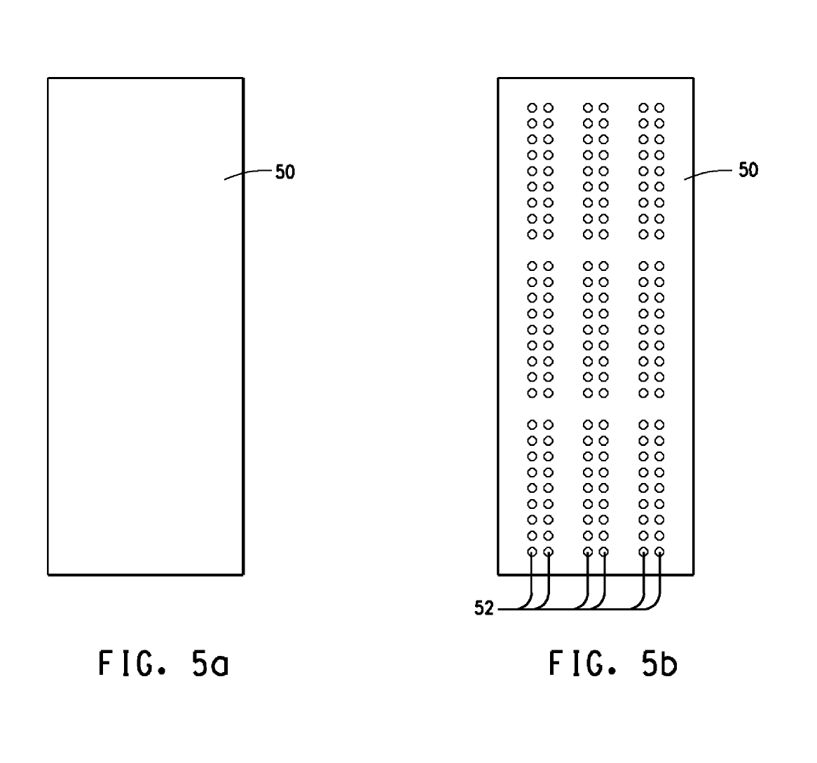

An ILD layer is shown in FIG. 5a. The ILD is in the form of a sheet that covers at least one column of solar cells in the solar cell array, and preferably covers multiple columns of solar cells in the solar cell array or more preferably covers all of the columns of solar cells in the solar cell array. The sheet 50 is preferably comprised of an electrical insulating material such as a thermoplastic or thermoset polymer, and may be comprised of one or more of the materials that comprise wire mounting layer 38 as described above. For example, the ILD may be an insulating polymer film such as a polyester, polyethylene or polypropylene film. Alternatively, the ILD may be a reinforced polymer layer such as a glass fiber reinforced epoxy layer. The ILD preferably has a melting temperature that is greater than the peak lamination temperature applied during lamination of the photovoltaic module. The ILD may be made of a porous material such as an open glass or polymer mesh or weave through which a melted encapsulant or conductive adhesive can pass.

An encapsulant layer is preferably provided between the ILD and the back side of the solar cells. Encapsulant layers are used to encase the fragile voltage-generating photoactive layer so as to protect it from environmental or physical damage and hold it in place in the photovoltaic module. Suitable polymer materials for the encapsulant layer typically possess a combination of characteristics such as high impact resistance, high penetration resistance, high moisture resistance, good ultraviolet (UV) light resistance, good long term thermal stability, adequate adhesion strength to other rigid polymeric sheets and cell surfaces, and good long term weatherability. The uncured polymers that may be used in the wire mounting layer described above can also be used in encapsulant layers, as for example, ethylene methacrylic acid and ethylene acrylic acid, ionomers derived therefrom, or combinations thereof. Exemplary comonomers that may be in the precursor acid copolymers include, but are not limited to, methyl acrylates, methyl methacrylates, butyl acrylates, butyl methacrylates, glycidyl methacrylates, vinyl acetates, and mixtures of two or more thereof. Suitable encapsulants include poly(vinyl butyral)(PVB), ionomers, ethylene vinyl acetate (EVA), poly(vinyl acetals) (including acoustic grade poly(vinyl acetals)), polyurethanes, polyvinylchlorides, polyethylenes, polyolefin block elastomers, copolymers of a-olefins and a,β-ethylenically unsaturated carboxylic acid esters (e.g., ethylene methyl acrylate copolymers and ethylene butyl acrylate copolymers), silicone elastomers, polycarbonate resins, epoxy resins, nylon resins and combinations of two or more thereof.

In one embodiment, the ILD is comprised of a PET polymer film that is coated with or laminated to an adhesive or an encapsulant layer such as an EVA film. During lamination, the adhesive or encapsulant layer adheres to the back to the solar cells and serves to seal and protect the cells while the polyester layer remains intact to serve as an insulator between the conductive wires and the back of the solar cells. Preferably the ILD and the encapsulant layer are comprised of a material that can be die cut or punched, or that can be formed with openings in it. The ILD may also be coated with an adhesive, such as a pressure sensitive adhesive, on the side of the ILD that will initially be contacted with the conductive wires and wire mounting layer. Suitable adhesive coatings on the ILD include pressure sensitive adhesives, thermoplastic or thermoset adhesives such as the ethylene copolymers discussed above, or acrylic, epoxy, vinyl butryal, polyurethane, or silicone adhesives. As shown in FIG. 5b, openings 52 are formed in the ILD. These openings will correspond to the arrangement of the solar cell back contacts when the ILD is positioned between the conductive wires of the integrated back-sheet and the back of the solar cell array. Preferably, the openings are formed by punching or die cutting the ILD, but alternatively the ILD can be formed with the openings. When an encapsulant layer is used between the ILD and the solar cells, the encapsulant layer will preferably have openings aligned with the openings in the ILD.

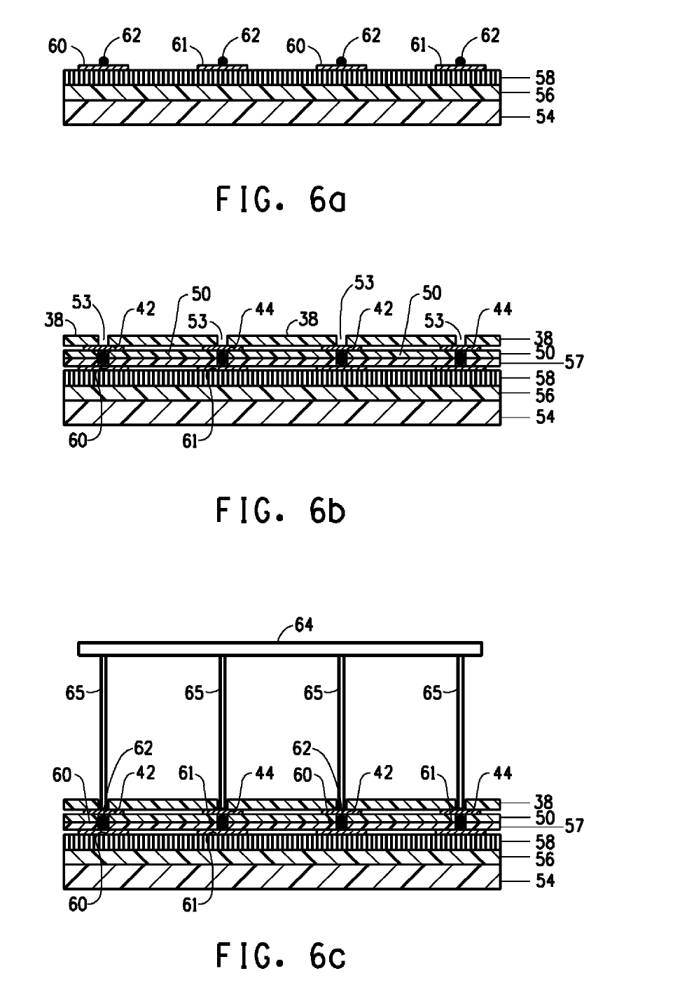

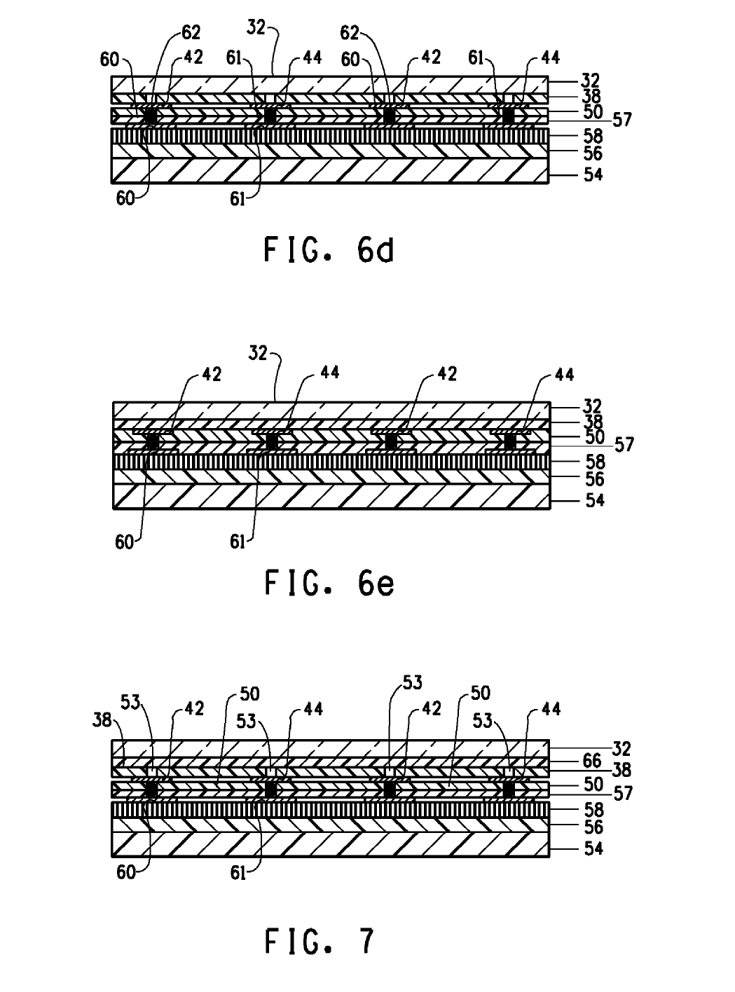

FIGS. 6a-6d illustrate in partial cross section the steps of one disclosed process for making a back-contact solar module with an integrated glass back-sheet. FIGS. 6a-6d show the formation of a portion of a photovoltaic module around one solar cell of a solar cell array. As shown in FIG. 6a, a transparent front sheet 54, made of glass or a polymer such as a durable fluoropolymer film, is provided. The transparent front sheet typically has a thickness of from 2 to 4 mm for glass front sheet or 50 to 250 microns for polymer front sheet. The rigid glass sheet 32 in the back-sheet makes it possible for the front sheet 54 to be a flexible and durable polymer film or sheet such as a fluoropolymer sheet. Where preventing moisture ingress is of primary importance, such as where the solar cells are CIGS solar cells, it may be desirable for both the front and back sheets to be glass sheets. A front encapsulant layer 56 may be applied over the front sheet 54. The encapsulant may be comprised of any of the uncured encapsulant or adhesive materials described above, such as uncured EVA. The front encapsulant layer typically has a thickness of from 200 to 500 microns. The front encapsulant layer must be transparent to light.

FIGS. 6a-6d show one photoactive solar cell 58 of the solar cell array, such as a crystalline silicon solar cell, provided on the encapsulant layer 56. The solar cell has all of its electrical contacts on the back side of the solar cell. The best known types of back-contact solar cells are metal wrap through (MWT), metal wrap around (MWA), emitter wrap through (EWT), emitter wrap around (EWA), and interdigitated back contact (IBC). Electrical conductors on the light receiving front side of the solar cell (facing the transparent front sheet) are connected through vias in the solar cell to back side conductive pads 60, while a back side conductive layer (not shown) is electrically connected to back side contact pads 61. The back contact pads are typically silver pads fired on the solar cells from a conductive paste of silver particles and glass frit in an organic carrier medium.

A small portion of a solder or of a polymeric electrically conductive adhesive is provided on each of the contact pads 60 and 61. The portions of solder or conductive adhesive are shown as balls 62 in FIG. 6a. The solder may be a conventional solder, such as 60/40 tin lead, 60/38/2 tin lead silver, other known solder alloys, or a low melting point solder, such as low melting point solder containing indium that melts around or below 160° C. The conductive adhesive may be any known conductive adhesive, such as an adhesive comprised of conductive metal particles, such as silver, nickel, conductive metal coated particles or conductive carbon suspended in epoxies, acrylics, vinyl butryals, silicones or polyurathanes. Preferred conductive adhesives are aniostropically conductive or z-axis conductive adhesives that are commonly used for electronic interconnections.

FIG. 6b shows the application of a back encapsulant layer 57 and an ILD 50, like the layer shown and described with regard to FIG. 5b, over the back of the solar cell array. FIG. 6b also shows the application of electrically conductive ribbon-shaped wires 42 and 44 over the back contacts 60 and 61 of the solar cell 58. The conductive wires 42 and 44 are provided on the wire mounting layer 38 as described above. The wire mounting layer 38 shown in FIG. 6b has holes 53 in the surface that are formed, cut or punched in the wire mounting layer over the areas where the conductive wires are to be connected to the back contacts of the solar cell. As shown in FIG. 6c, heating pins 65 of a welding apparatus 64 are arranged to be applied to the conductive wires through the holes 53 in the wire mounting layer 38. The heating pins 65 may be in a spring loaded “bed of nails” arrangement so as to be able to contact numerous points on the conductive wires at the same time. The pins 65 heat the portions of the wires over the back contacts and can press the wires into engagement with the balls 62 of solder or adhesive polymer. When the wires are soldered to the back contacts, the pins 65 heat the portions of the wires over the back contacts of the solar cell to a temperature in the range of about 150° C. to 700° C., and more typically 400° C. to 600° C. Solders that melt at lower temperatures, such as 160° C., are also useful in the disclosed process.

As shown in FIG. 6d, the heated pins 65 are removed and the glass sheet 32 is applied over the side of the wire mounting layer 38 that is opposite the wires 42 and 44. The entire stack is then subjected to heat lamination, as for example in a heated vacuum press. The wire mounting layer 38 becomes adhered between the glass sheet 32 and the ILD 50. The back encapsulant layer 57 seals the back of the solar cell 58 and adheres the ILD 50 to the back of the solar cell 58.

When a conductive adhesive is used to attach and electrically connect the conductive wires to the back contacts of the solar cells, the conductive adhesive may be heated above its softening temperature with the heated pins 65 as described above with regard to FIG. 6c, but where conductive adhesive is used in place of the solder. More preferably, the conductive adhesive can be selected to have a softening temperature close to the lamination temperature that must be applied to the encapsulant layers during lamination of the module so as to melt and cure the encapsulant and cause the adhesive polymer to electrically connect and bond the solar cell back contacts and the conductive wires during the thermal lamination of the solar module. In this alternative embodiment, where the conductive adhesive 62 is softened during lamination, it is not necessary for the wire mounting layer 38 to have holes in it through which heating pins can pass. However, when the conductive wires are not bonded to the solar cell back contacts prior to the heated lamination of the solar module, it may be necessary to use other means to hold the conductive wires 42 and 44 in place during lamination of the solar module.

This can be accomplished by making the wire mounting layer 38 more rigid by curing the wire mounting layer after the conductive wires are applied and adhered to the mounting layer and before the solar module lamination steps. Curing of the wire mounting layer is done by heating the wire mounting layer to a point above the cross linking temperature of a curable polymer that makes up the wire mounting layer in a range of 120 to 160° C. for a specified time of 5 to 60 minutes. As shown in FIGS. 7, an additional layer 66 of an encapsulant or a suitable adhesive can be applied over the cured wire mounting layer 38 before application of the protective glass sheet 32. When the module is laminated, the layer 66 adheres the glass to the cured wire mounting layer 38, and the encapsulant layer 57 seals the back of the solar cell 58 and adheres the ILD 50 to the back of the solar cell 58.

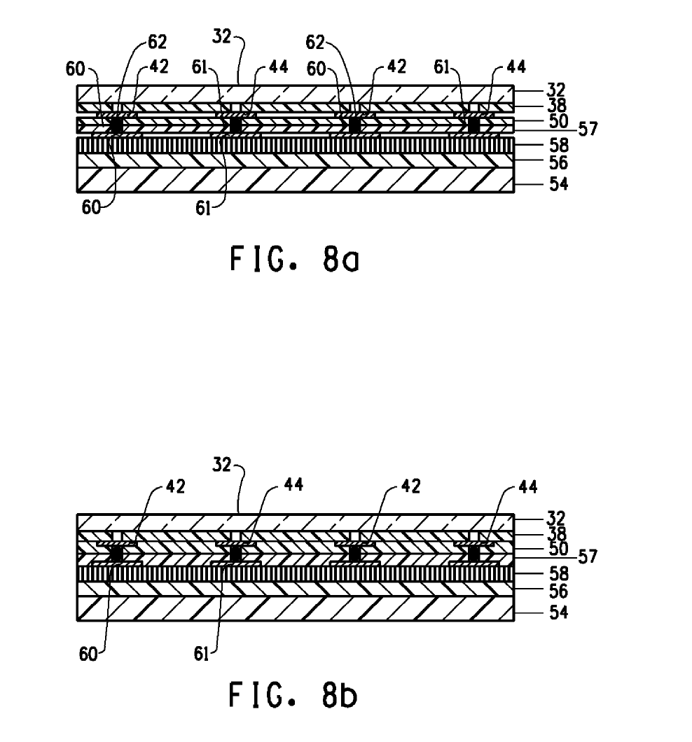

FIGS. 8a and 8b illustrate an alternative process for holding the conductive wires in place over the solar cell back contacts where a conductive adhesive 62 is used to bond and electrically connect the solar cell back contacts and the conductive wires. The conductive adhesive 62 is selected to have a curing temperature that is sufficiently below the melting and curing temperature of the encapsulant such that conductive adhesive can be cured after the conductive wires are applied over the solar cell back contacts but before the solar module is laminated. For example, the conductive adhesive may be selected to have a curing temperature of from room temperature to about 100° C. so that the conductive adhesive can be melted and cured so as to firmly attach the conductive wires 42 and 44 to the back contacts 60 and 61, respectively, before the overall module is laminated. Subsequently, the module is laminated and cured at a higher temperature of about 100 to 180° C. during which the wire mounting layer 38 (as shown in FIG. 8a) adheres the glass sheet 32 to the ILD 50. The encapsulant layer 57 seals the back of the solar cell 58 and adheres the ILD 50 to the back of the solar cell 58. During module lamination, the conductive wires are held in place and in contact with the solar cell back contacts by the pre-cured conductive adhesive.

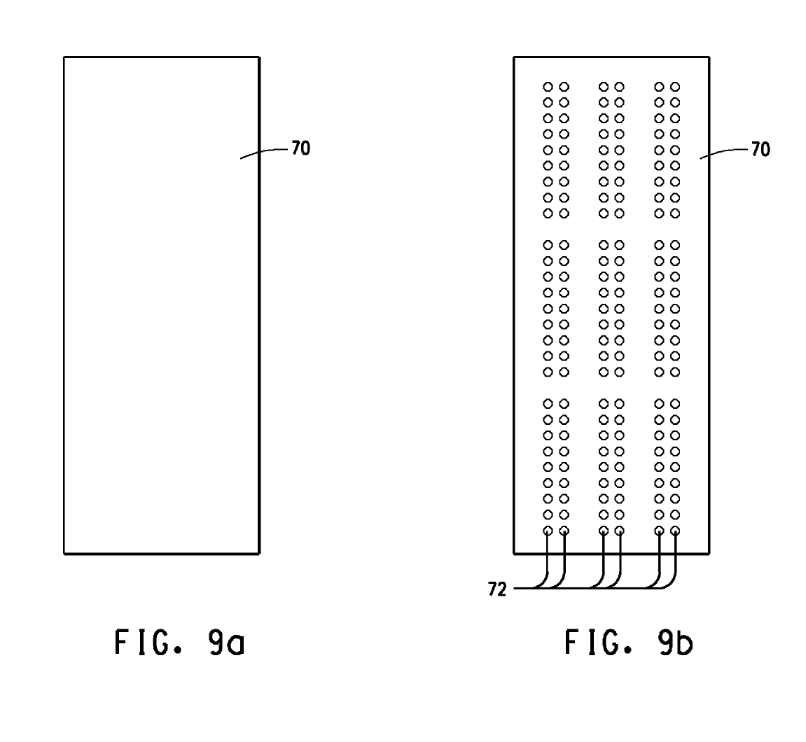

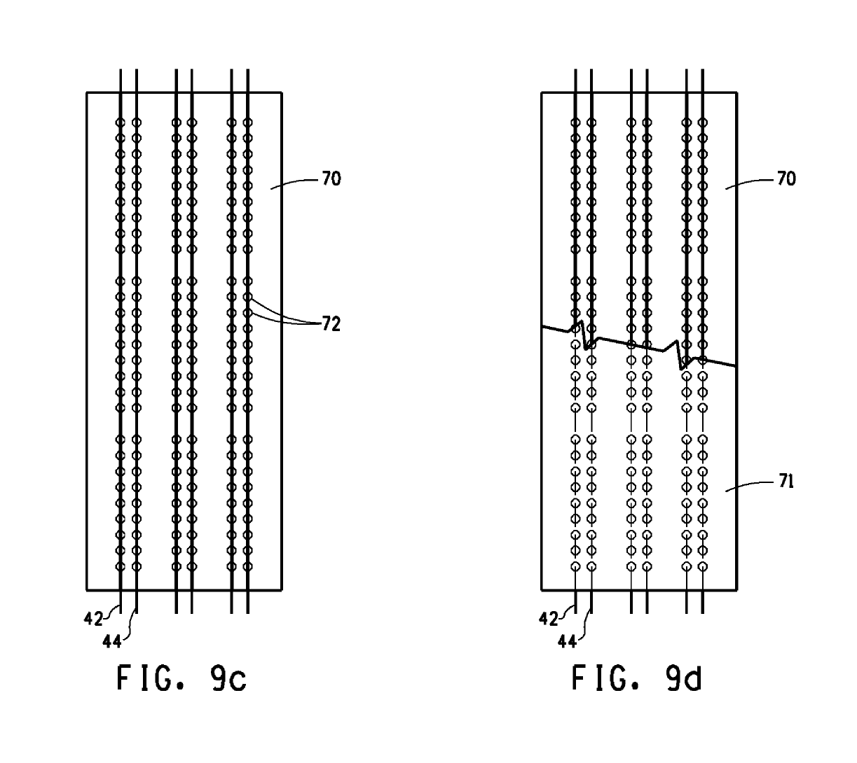

In an alternative embodiment, the ILD can serve as the both the wire mounting layer and as the ILD between the back side of the solar cells and the conductive wires. As shown in FIG. 9a, a wire mounting layer 70 is provided. The wire mounting layer may be comprised of any of the polymeric materials described above with regard to the wire mounting layer 38 of FIG. 4a. The layer 70 may be a solid polymer sheet, a glass fiber reinforced sheet, or an open mesh or weave into which an encapsulant melt can penetrate. As shown in FIG. 9b, holes 72 are punched, die cut or formed in the layer 70 at places that correspond to where the wire mounting layer will be positioned over the back contacts of a solar cell when the wire mounting layer is placed on the back side of a solar cell. As shown in FIG. 9c, conductive wires 42 and 44 are adhered to the uncured wire mounting layer 70 over columns of the holes 72. The conductive wires are adhered to or embedded in the surface of the wire mounting layer as described above. Where the conductive wires will be used to connect solar cells in parallel, the continuous conductive wires are used as shown in FIG. 9c. Where the solar cells are to be connected in series, the conductive wires are selectively cut. Cutting the wires can be performed by a variety of methods including mechanical die cutting, rotary die cutting, mechanical drilling, or laser ablation.

The wire mounting layer is then cured, as for example by heating the wire mounting layer above a temperature where cross-linking occurs in the wire mounting layer. As shown in FIG. 9d, an additional wire cover layer 71, comprised of the same or a similar material as used in the uncured wire mounting layer 70, is applied over the conductive wires and the wire mounting layer 70. The wire mounting layer 70, the conductive wires 42 and 44, and the wire cover layer 71 can be fed into a heat press or a nip formed between heated rollers in order to produce the wire containing back-sheet substructure shown in FIG. 9d. This substructure may be utilized in several ways in the production of back-contact solar cell modules. The substructure of FIG. 9d can be adhered to the glass sheet 32 by thermal or adhesive lamination wherein the exposed surface of the wire cover layer 71 is adhered to the glass sheet. This integrated back-sheet can subsequently be laminated to the back side of a solar cell where the wire mounting layer 70 will be adhered to the back side of the solar cells in a manner such that the holes or openings 72 are positioned over the back contacts of the solar cell. Preferably, a polymeric encapsulant layer with openings aligned with the holes 72 of the wire mounting layer 70 is inserted between the cured wire mounting layer and the back of the solar cells. A conductive adhesive can be applied in each of the holes or openings 72 of the wire mounting layer 70 before the wire mounting layer is positioned over the encapsulant layer and the back side of the solar cells such that the conductive adhesive will bond and electrically connect the back contacts of the solar cell to the conductive wires during module lamination. Alternatively, the substructure shown in FIG. 9d, with conductive adhesive applied in the holes or openings 72, can be applied to an encapsulant layer with corresponding holes which layer is over the back side of a solar cell array. The conductive adhesive in the holes of the wire mounting layer 70 contacts the back contacts on the back side of the solar cells through the holes in the encapsulant layer.

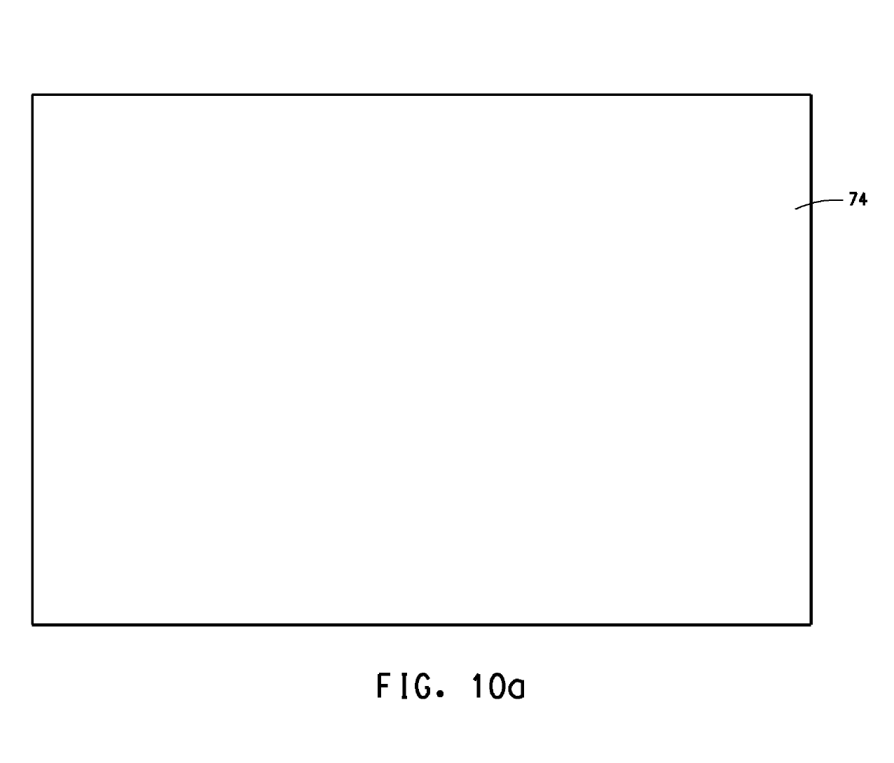

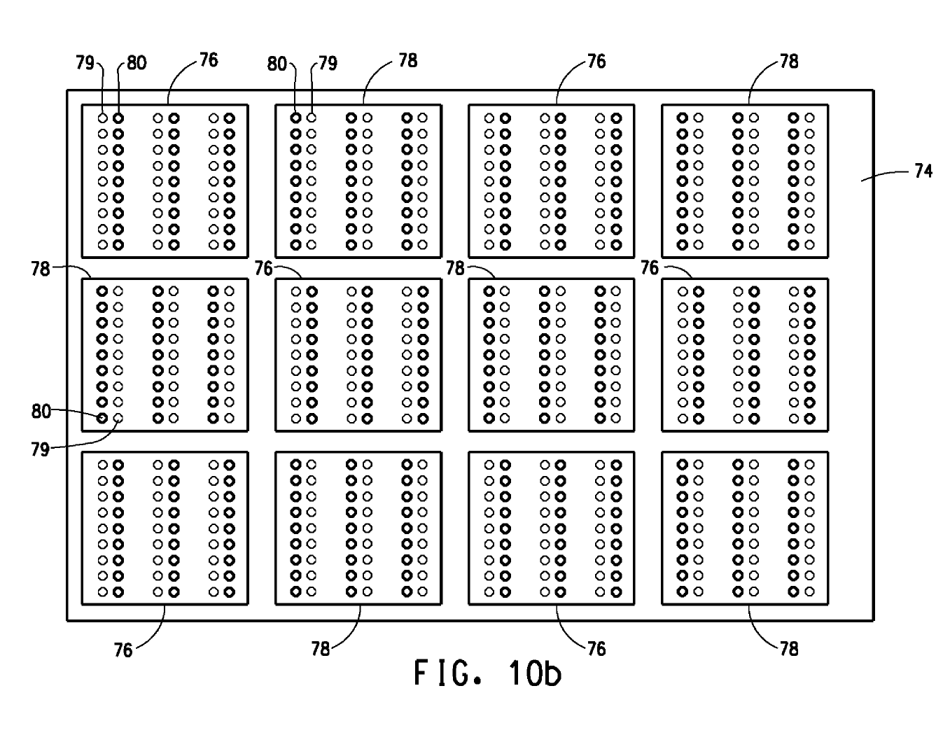

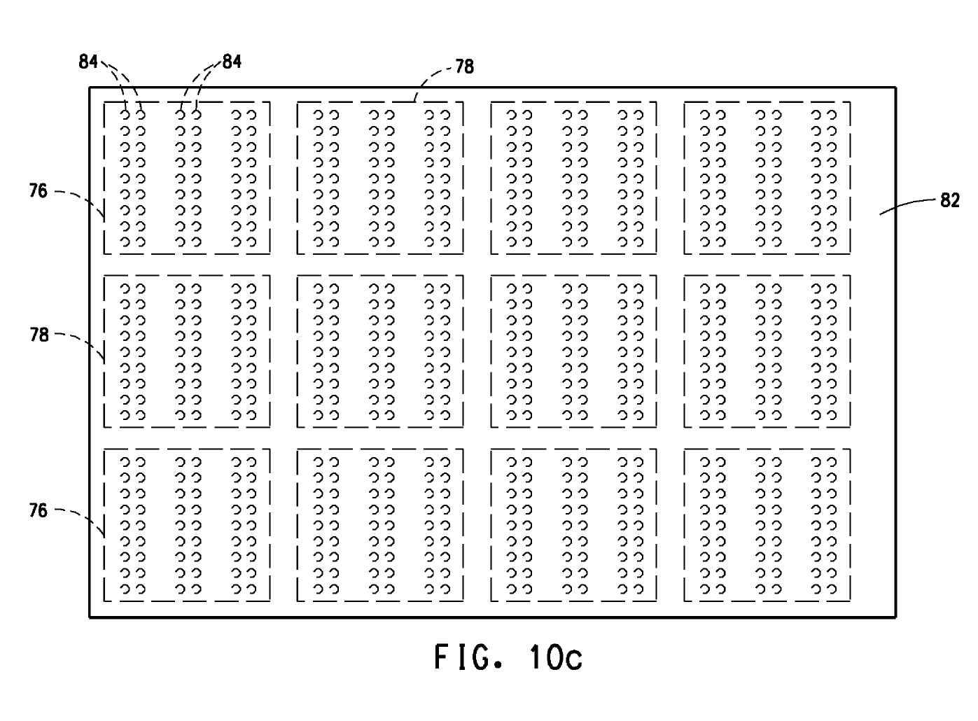

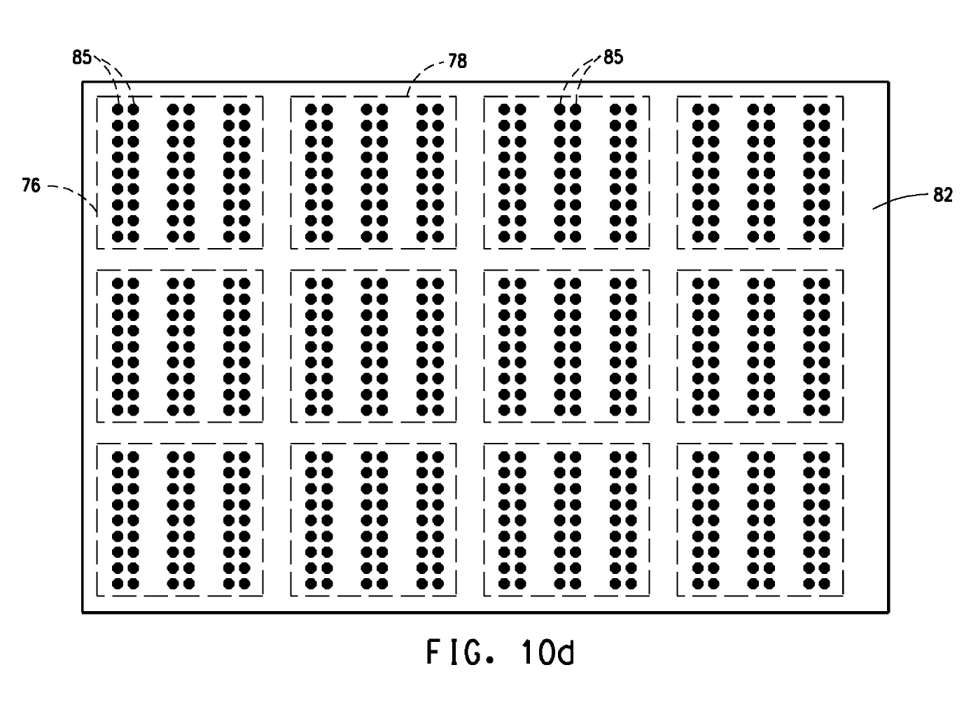

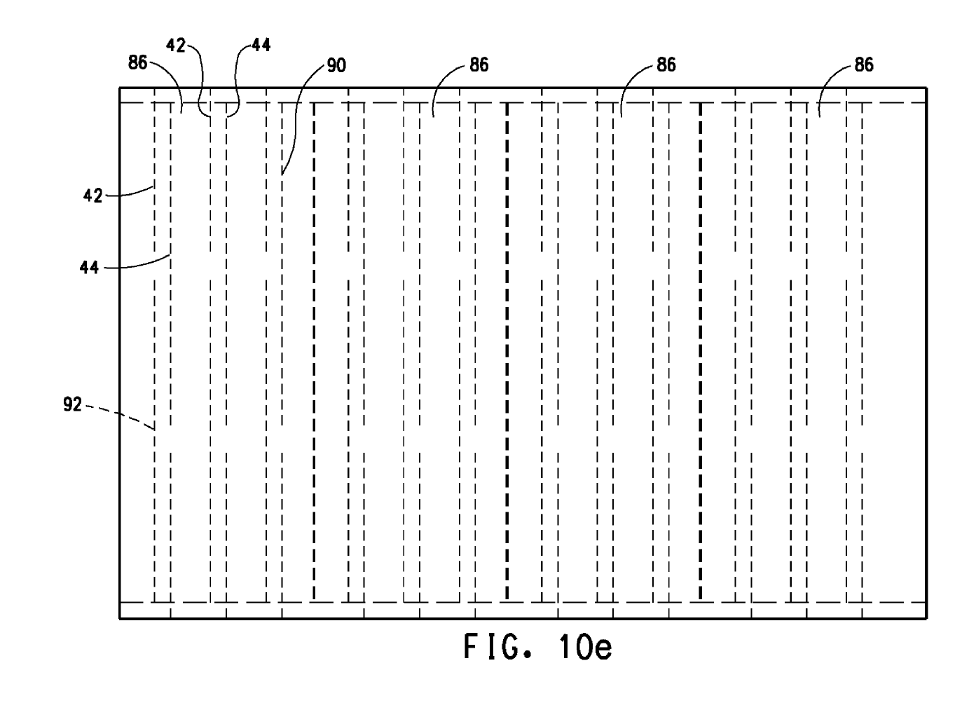

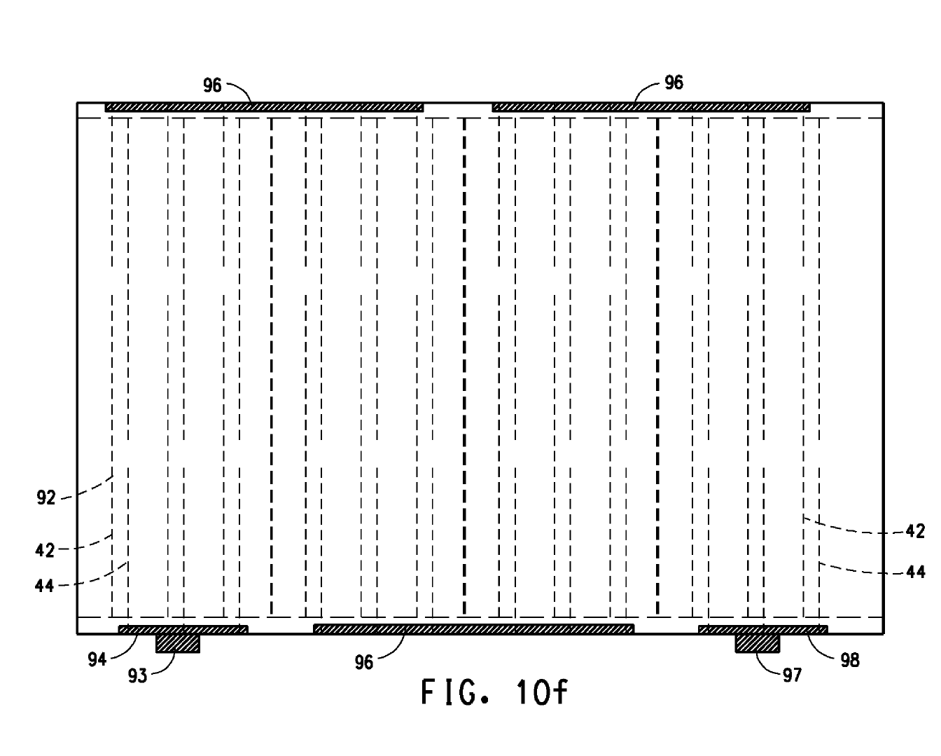

A process for forming a back contact solar cell module with a solar cells connected in series by an integrated back-sheet is shown in FIGS. 10a-10f. According to this process, a front encapsulant layer 74 is provided as shown in FIG. 10a. The front encapsulant layer may be comprised of one of the encapsulant or adhesive sheet materials described above. The front encapsulant layer may be an independent self supporting sheet that can be adhered on its front side to a transparent front sheet (not shown) such as a glass or polymer front sheet, or it may be a sheet, coating or layer already adhered on a transparent front sheet such as a transparent and flexible fluoropolymer film or sheet. As shown in FIG. 10b, an array of back contact solar cells 76 and 78 are placed on the surface of the encapsulant layer 74 opposite to the front sheet side of the encapsulant layer. The solar cells 76 and 78 are placed with their front light receiving sides facing against the front encapsulant layer 74. Each of the solar cells has columns of positive and negative polarity back contacts with the negative contacts represented by the lighter circles 79 and the positive contacts represented by darker circles 80 in FIG. 10b. In the cells 76, in each pair of back contacts, a positive contact 80 is to the right of a negative contact 79. The cells 78 are rotated 180 degrees such that in each pair of back contacts, a negative contact 79 is to the right of one of the positive contacts 80. The cells 76 alternate with the cells 78 in both the vertical and horizontal directions of the solar cell array. It is contemplated that in other embodiments, there could be more of the positive or more of the negative contacts on the solar cells, or that there could be more or fewer columns of either the positive or negative back contacts. While FIG. 10b shows a cell 76 in the upper left hand corner of the solar cell array, it is contemplated that the cells could be arranged with a cell 78 in the upper left hand corner and with a cells 76 arranged below and next to the upper left hand corner cell 78. While the solar cell placements 76 and 78 are shown as alternating in both the vertical and horizontal directions of the array, it is also contemplated that in an array of series connected solar cells, the cell placements 76 and 78 could be alternated only in the vertical direction.

In FIG. 10c, an encapsulant layer (not shown) and is placed over the back of the solar cell array and an ILD 82 is place over the encapsulant. The encapsulant layer may be comprised of any of the polymeric encapsulant materials discussed above. The ILD may be comprised of any of the materials described above with regard to the ILD 50 shown in FIG. 6b. The ILD 82 preferably has a thickness of about 1 to 10 mils. Holes 84 are preformed, cut or punched in the encapsulant and ILD layers over where the back contacts of the solar cell array will be located. In FIG. 10d, the holes or openings in the encapsulant and ILD layers are shown filled with a conductive adhesive dabs 85 which may be screen printed in the holes 84 of the ILD 82, or alternatively may be applied by syringe or other application method.

In FIG. 10e, one or more wire mounting layer strips 86 with longitudinally extending wires 42 and 44, like the wire substructure shown and described with regard to FIG. 4b, are provided and applied over the ILD 82. The wires 42 and 44 are provided over sets of positive and negative back contacts on the solar cells. The side of the wire mounting layer strips 86 on which the wires are exposed is positioned so that the conductive wires 42 and 44 contact the conductive adhesive dabs 85 in the holes of the ILD 82. In one embodiment, the side of the wire mounting layer strips opposite the side on which the wires are mounted is already adhered to a glass sheet like the sheet 32 described above. It is contemplated that all of the conductive wires 42 and 44 required for a module could be adhered to a single wire mounting layer strip that covers the entire solar cell array of a solar module.

As shown in FIGS. 10e and 10f, one of the wires 42 and 44 have been selectively cut between each set of solar cells in a column of solar cells in the solar cell array. The wires may be cut by mechanical die cutting, rotary die cutting, mechanical drilling or laser ablation. Cutting of the wires may also be performed by punching a hole through both the wire and the wire mounting layer, which hole will be filled during module lamination by polymer flowing from the wire mounting layer or from the encapsulant or adhesive layer between the wire mounting layer and the glass back-sheet. As shown in FIG. 10e, the wires 42 are positioned over columns of the solar cell back-contacts 79 of negative polarity that can be seen in FIG. 10b, and the wires 44 are positioned over the columns of back-contacts 80 of positive polarity of the solar cell 76 shown in FIG. 10b in the upper left corner of the solar cell array. The wires 42 are cut between where the wires 42 contact the solar cell 76 and where they contact the solar cell 78 which has been rotated 180 degrees and that is positioned below the cell 76. The wires 44 which are positioned over the positive polarity contacts on the upper left solar cell 76 runs continuously over the negative contacts on the solar cell 78 positioned below the upper left solar cell 76 so as to connect the positive polarity contacts of the one cell in series to the negative polarity contacts of the next cell. The wires 44 are cut between where the wires 44 are positioned over the cell 78 and where they are positioned over the next cell 76 at the bottom right side of the solar cell array that can be seen in FIG. 10b. On the other hand, the wires 42 that are positioned over the positive contacts of the middle cell in the left hand column of the solar cell array run continuously to where the wires 42 are positioned over the negative contacts of the solar cell 76 at the bottom right side of the solar cell array as can be seen in FIG. 10b. This pattern is repeated for as many solar cells as there are in the columns of the solar cell array. In FIG. 10e, the wires 42 and 44 are shown as being attached to four wire mounting layer strips 86, but it is contemplated that the wires could all be mounted, and optionally precut, on just one or two wire mounting layer strips that cover the entire solar cell array.

FIG. 10f shows the application of bus connections 94, 96, and 98 on the ends of the solar module. The terminal buss 94 connects to the wires 44 that are over and will connect to the positive back-contacts on the solar cell at the bottom left hand side of the solar cell array. Likewise, the terminal buss 98 connects to the wires 44 that are over the negative back-contacts on the solar cell at the bottom right hand side of the solar cell array. Positive terminal buss 94 is connected to a positive lead 93 and the negative terminal buss 98 is connected to a negative lead 97. The intermediate buss connectors 96 connect the positive or negative back contacts at the top or bottom of one column of solar cells to the oppositely charged contacts at the same end of the adjoining column of solar cells. The terminal buss connections may alternately be extended through the “Z” direction out through the glass back sheet. This would eliminate the need for extra space at the ends of the module for running the buss wires to the junction box. Such “extra space” would reduce the packing density of the cells and reduce the electric power output per unit area of the module.

The solar cell array shown in FIG. 10 is simplified for purpose of illustration and shows only four columns of three solar cells, and each solar cell is shown with just three columns of positive and three columns of negative back contacts. It is contemplated that the solar cell array of the solar module could have many more columns or rows of individual solar cells, and that each solar cell could have fewer or more columns or rows of back contacts than what is shown in FIG. 10.

The photovoltaic module of FIG. 10 may be produced through autoclave and non-autoclave processes. For example, the photovoltaic module constructs described above may be laid up in a vacuum lamination press and laminated together under vacuum with heat and standard atmospheric or elevated pressure. In an exemplary process, a polymer front sheet, a front-sheet encapsulant layer, a back-contact photovoltaic cell layer, a back encapsulant layer, an ILD, a layer of longitudinally extending wires on a polymeric wire mounting layer, and a glass back sheet as disclosed above are laminated together under heat and pressure and a vacuum (for example, in the range of about 27-28 inches (689-711 mm) Hg) to remove air. In an exemplary procedure, the laminate assembly is placed into a bag capable of sustaining a vacuum (“a vacuum bag”), drawing the air out of the bag using a vacuum line or other means of pulling a vacuum on the bag, sealing the bag while maintaining the vacuum, placing the sealed bag in an autoclave at a temperature of about 120° C. to about 180° C., at a pressure of from 50 to 250 psig, and preferably about 200 psi (about 14.3 bars), for from about 10 to about 50 minutes. Preferably the bag is autoclaved at a temperature of from about 120° C. to about 160° C. for 20 minutes to about 45 minutes. More preferably the bag is autoclaved at a temperature of from about 135° C. to about 160° C. for about 20 minutes to about 40 minutes.

Air trapped within the laminate assembly may be removed using a nip roll process. For example, the laminate assembly may be heated in an oven at a temperature of about 80° C. to about 120° C., or preferably, at a temperature of between about 90° C. and about 100° C., for about 30 minutes. Thereafter, the heated laminate assembly is passed through a set of nip rolls so that the air in the void spaces between the photovoltaic module outside layers, the photovoltaic cell layer and the encapsulant layers may be squeezed out, and the edge of the assembly sealed. This process may provide a final photovoltaic module laminate or may provide what is referred to as a pre-press assembly, depending on the materials of construction and the exact conditions utilized. The pre-press assembly may then be placed in an air autoclave where the temperature is raised to about 120° C. to about 160° C., or preferably, between about 135° C. and about 160° C., and the pressure is raised to between about 50 psig and about 300 psig, or preferably, about 200 psig (14.3 bar). These conditions are maintained for about 15 minutes to about 1 hour, or preferably, about 20 to about 50 minutes, after which, the air is cooled while no more air is added to the autoclave. After about 20 minutes of cooling, the excess air pressure is vented and the photovoltaic module laminates are removed from the autoclave. The described process should not be considered limiting. Essentially, any lamination process known within the art may be used to produce the back contact photovoltaic modules with integrated back circuitry as disclosed herein.

If desired, the edges of the photovoltaic module may be sealed to reduce moisture and air intrusion by any means known within the art. Such moisture and air intrusion may degrade the efficiency and lifetime of the photovoltaic module. Edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

While the presently disclosed invention has been illustrated and described with reference to preferred embodiments thereof, it will be appreciated by those skilled in the art that various changes and modifications can be made without departing from the scope of the present invention as defined in the appended claims.

What is claimed is:

1. A process for making an integrated back-sheet for a back contact solar cell module with a plurality of electrically connected solar cells, comprising:
providing a polymeric wire mounting layer having opposite first and second sides and having a lengthwise length and direction and a crosswise direction perpendicular to the lengthwise direction;
providing a plurality of elongated electrically conductive wires and adhering said plurality of electrically conductive wires to the first side of said polymeric wire mounting layer in the lengthwise direction of said polymeric wire mounting layer, said electrically conductive wires being substantially aligned with the lengthwise direction of said polymeric wire mounting layer, said plurality of electrically conductive wires each having a cross sectional area of at least 70 square mils along their length, said plurality of electrically conductive wires not touching each other upon being adhered to said polymeric wire mounting layer, and said plurality of electrically conductive wires extending at least two times the length of a solar cell of the back-contact solar cell module;
providing a glass back-sheet, and adhering said second side of said polymeric wire mounting layer to said glass back-sheet;
providing a polymeric interlayer dielectric layer having opposite first and second sides and having a lengthwise length and direction and a crosswise direction perpendicular to the lengthwise direction, and forming openings in said polymeric interlayer dielectric layer, said openings being arranged in a plurality of columns extending in the lengthwise direction of said polymeric interlayer dielectric layer;
arranging the plurality of columns of openings in said interlayer dielectric layer over the electrically conductive wires adhered to the wire mounting layer such that the openings in each column of openings are aligned with and over one of the plurality of electrically conductive wires; and
attaching the polymeric interlayer dielectric layer to polymeric wire mounting layer.

2. The process for making an integrated back-sheet of claim 1 wherein said glass back-sheet has a thickness of from 1.5 to 4 mm.

3. The process for making an integrated back-sheet of claim 1 wherein the polymeric wire mounting layer is cured before the polymeric interlayer dielectric layer is attached to the wire mounting layer.

4. The process for making an integrated back-sheet of claim 3 wherein after the electrically conductive wires are adhered to the polymeric wire mounting layer, the polymeric wire mounting layer is cured by heating the polymeric wire mounting layer to the curing temperature of the polymeric wire mounting layer.

5. The process for making an integrated back-sheet of claim 1 wherein said polymeric wire mounting layer is comprised of a polymer selected from poly(vinyl butyral), ionomers, ethylene vinyl acetate, poly(vinyl acetal), polyurethane, poly(vinyl chloride), polyolefins, polyolefin block elastomers, ethylene acrylate ester copolymers, ethylene copolymers, silicone elastomers, polycarbonate resins, epoxy resins, nylon resins and combinations thereof.

6. The process for making an integrated back-sheet of claim 5 wherein said polymeric wire mounting layer is an ethylene copolymer comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer accounts for 60-90% by weight.

7. The process for making an integrated back-sheet of claim 1 wherein said polymeric interlayer dielectric layer is comprised of poly(vinyl butyral), ionomers, ethylene vinyl acetate, poly(vinyl acetal), polyurethane, poly(vinyl chloride), polyolefins, polyolefin block elastomers, ethylene acrylate ester copolymers, ethylene copolymers, silicone elastomers, chlorosulfonated polyethylene, epoxy and combinations thereof.

8. The process for making an integrated back-sheet of claim 1 further comprising the step of selectively cutting one or more of said electrically conductive wires at one or more selected points along the length of said electrically conductive wires.

9. A process for making a back-contact solar cell module, comprising:
providing a solar cell array of at least four solar cells each having a front light receiving surface, an active layer that generates an electric current when said front light receiving surface is exposed to light, and a rear surface opposite said front surface, said rear surface having positive and negative polarity electrical contacts thereon, at least two of the solar cells of the solar cell array arranged in a column;
providing a polymeric wire mounting layer having opposite first and second sides and having a lengthwise direction and a crosswise direction perpendicular to the lengthwise direction;
providing a plurality of elongated electrically conductive wires and adhering said plurality of electrically conductive wires to the first side of said polymeric wire mounting layer in the lengthwise direction of said polymeric wire mounting layer, said electrically conductive wires being substantially aligned with the lengthwise direction of said polymeric wire mounting layer, said plurality of electrically conductive wires each having a cross sectional area of at least 70 square mils along their length, said plurality of electrically conductive wires not touching each other upon being adhered to said polymeric wire mounting layer, and said plurality of electrically conductive wires extending at least the length of a column of the solar cells in the solar cell array;
providing a polymeric interlayer dielectric layer having opposite first and second sides and having a lengthwise length and direction and a crosswise direction perpendicular to the lengthwise direction, and forming openings in said polymeric interlayer dielectric, said openings being arranged in a plurality of columns extending in the lengthwise direction of said polymeric interlayer dielectric layer;
placing the interlayer dielectric layer between the rear surface of the solar cells of the solar cell array and the first side of the wire mounting layer, and arranging the plurality of columns of openings in said interlayer dielectric layer over the electrically conductive wires adhered to the wire mounting layer such that the openings in each column of openings are aligned with and over one of the plurality of electrically conductive wires, and aligning the openings in said interlayer dielectric layer with the positive and negative polarity contacts on the rear surfaces solar cells of the solar cell array, wherein said positive and negative polarity electrical contacts on said solar cells are electrically connected to said electrically conductive wires through the openings in said polymeric interlayer dielectric layer;
adhering said polymeric interlayer dielectric layer to said first surface of the polymeric wire mounting layer and to said rear surface of the solar cells of the solar cell array;
providing a glass back-sheet, and attaching said second side of said polymeric wire mounting layer to said glass back-sheet.

10. The process for making a back-contact solar cell module of claim 9 wherein the polymeric wire mounting layer is cured before the polymeric interlayer dielectric layer is attached to the wire mounting layer.

11. The process for making a back-contact solar cell module of claim 10 wherein after the electrically conductive wires are adhered to the polymeric wire mounting layer, and the polymeric wire mounting layer is cured by heating the polymeric wire mounting layer to the curing temperature of the polymeric wire mounting layer.

12. The process for making a back-contact solar cell module of claim 9 wherein said polymeric wire mounting layer and said interlayer dielectric layer are comprised of a polymer selected from poly(vinyl butyral), ionomers, ethylene vinyl acetate, poly(vinyl acetal), polyurethane, poly(vinyl chloride), polyolefins, polyolefin block elastomers, ethylene acrylate ester copolymers, ethylene copolymers, silicone elastomers, polycarbonate resins, epoxy resins, nylon resins and combinations thereof.

13. An integrated back sheet for a solar cell module with a plurality of electrically connected solar cells, comprising:
a polymeric wire mounting layer having opposite first and second sides and having a lengthwise length and direction and a crosswise direction perpendicular to the lengthwise direction, said polymeric wire mounting layer having a length of at least two times the length of a solar cell in the solar cell module;
a plurality of elongated electrically conductive wires adhered to the first side of said polymeric wire mounting layer in the lengthwise direction of said polymeric wire mounting layer, said electrically conductive wires being substantially aligned with the lengthwise direction of said polymeric wire mounting layer, said plurality of electrically conductive wires each having a cross sectional area of at least 70 square mils along their length, said plurality of electrically conductive wires not touching each other upon being adhered to said polymeric wire mounting layer, and said plurality of electrically conductive wires extending at least two times the length of a solar cell in the solar cell module, at least one of said electrically conductive wires being cut at at least one selected point along the length of said electrically conductive wires; and
a glass back-sheet attached to the second side of said polymeric wire mounting layer.

14. A solar cell module, comprising:
a solar cell array of at least four solar cells arranged in at least one column having a length, each of said solar cells having a front light receiving surface, an active layer that generates an electric current when said front light receiving surface is exposed to light, and a rear surface opposite said front light receiving surface, said rear surfaces having positive and negative polarity electrical contacts thereon;
a polymeric wire mounting layer having opposite first and second sides and having a lengthwise direction and a crosswise direction perpendicular to the lengthwise direction;
a plurality of elongated electrically conductive wires adhered to the first side of said polymeric wire mounting layer in the lengthwise direction of said polymeric wire mounting layer, said electrically conductive wires being substantially aligned with the lengthwise direction of said polymeric wire mounting layer, said plurality of electrically conductive wires each having a cross sectional area of at least 70 square mils along their length, said plurality of electrically conductive wires not touching each other, and said plurality of electrically conductive wires extending at least the length of a column of the solar cells in the solar cell array;
a polymeric interlayer dielectric layer having opposite first and second sides and having a lengthwise length and direction and a crosswise direction perpendicular to the lengthwise direction, said polymeric interlayer dielectric layer having openings arranged in a plurality of columns extending in the lengthwise direction of said polymeric interlayer dielectric layer;
said interlayer dielectric layer adhered to the rear surface of the solar cells of the solar cell array and to the first side of the wire mounting layer, wherein the plurality of columns of openings in said interlayer dielectric layer are arranged over the electrically conductive wires adhered to the wire mounting layer such that the openings in each column of openings are aligned with and over one of the plurality of electrically conductive wires, and wherein the openings in said interlayer dielectric layer are aligned with the positive and negative polarity contacts on the rear surfaces solar cells of the solar cell array, wherein said positive and negative polarity electrical contacts on the rear surface of said solar cells are electrically connected to said electrically conductive wires through the openings in said polymeric interlayer dielectric layer; and
a glass back-sheet attached to said second side of said polymeric wire mounting layer.

15. The solar cell module of claim 14 wherein said polymeric wire mounting layer and said interlayer dielectric layer are comprised of a polymer selected from poly(vinyl butyral), ionomers, ethylene vinyl acetate, poly(vinyl acetal), polyurethane, poly(vinyl chloride), polyolefins, polyolefin block elastomers, ethylene acrylate ester copolymers, silicone elastomers, polycarbonate resins, epoxy resins, nylon resins and combinations thereof.

16. The solar cell module of claim 14 wherein said glass back-sheet has a thickness of from 1.5 to 4 mm.

17. The solar cell module of claim 14 wherein the electrically conductive wires are comprised of metal selected from copper, nickel, tin, silver, aluminum, and combination thereof, and wherein the electrically conductive wires are ribbon-shaped metal wires having a width and thickness wherein the wire width is at least three times greater than the wire thickness.

18. A solar cell module, comprising:
a solar cell array of at least four solar cells each having a front light receiving surface, an active layer that generates an electric current when said front light receiving surface is exposed to light, and a rear surface opposite said front light receiving surface, said rear surface having positive and negative polarity electrical contacts thereon, said solar cell array having a length and width;
a glass back-sheet, having first and second opposite sides, said glass back sheet having a length greater than or equal to the length of said solar cell array and a width greater than or equal to the width of said solar cell array;
a plurality of electrically conductive wires disposed between said glass back-sheet and said solar cell array and supported by said first side of said glass back-sheet, said electrically conductive wires being substantially aligned with the length of the glass back-sheet, said electrically conductive wires having a length of at least two times the length of a solar cell of the solar cell array, and said electrically conductive wires having a cross sectional area of at least 70 square mils along their length, said plurality of electrically conductive wires not touching each other;
a polymeric insulating layer having opposite first and second sides disposed between said plurality of electrically conductive wires and said solar cell array, said first side of said polymeric insulating layer being adhered to the rear surface of the solar cells of the solar cell array and said second side of said polymeric insulating layer being adhered to said plurality of electrically conductive wires, said polymeric insulating layer having openings over the positive and negative contacts on the rear surface of the solar cells of the solar cell array, wherein said positive and negative contacts on said solar cells are electrically connected to one of said electrically conductive wires through the opening in said polymeric insulating layer over the electrical contacts.

19. The solar cell module of claim 18 wherein said second side of said polymeric insulating layer is adhered to said first side of said glass back-sheet.

20. The solar cell module of claim 18, further comprising a polymeric encapsulant layer, said polymeric encapsulant layer disposed between said plurality of electrically conductive wires and said first side of said glass back-sheet, said polymeric encapsulant layer having opposite first and second sides, the first side of said polymeric encapsulant layer being adhered to the second side of the polymeric insulating layer such that the plurality of electrically conductive wires are sandwiched between said polymeric encapsulant layer and said polymeric insulating layer, and the second side of said polymeric encapsulant layer being adhered to said first side of said glass back-sheet.
